(19) United States
(12) Patent Application Publication
(10) Pub. No.: US 2003/0042480 A1
(43) Pub. Date: Mar. 6, 2003

(54) Power transistor, semiconductor substrate for devices and method for manufacturing same

(76) Inventor: Fumihiko Hirose, Yokohama (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/225,195

(22) Filed: Aug. 22, 2002

(30) Foreign Application Priority Data
Aug. 23, 2001 (JP) 2001-252437

(51) Int. Cl. H01L 29/06

(52) U.S. Cl. 257/19

(57) ABSTRACT

A power transistor includes an n⁺ Si substrate, which has a surface intended for deposition, which is cleaned by wet chemical cleaning and further cleaned by vacuum heated cleaning, an n⁻ Si buffer layer, which is deposited on the Si substrate as a deposition by CVD to cover impurities remaining on the surface intended for deposition, a p SiGe base layer, which is deposited as a deposition on the Si buffer layer by CVD, an n Si emitter layer on the SiGe base layer, a base electrode, an emitter electrode, and a collector electrode.

### CROSS-REFERENCE TO RELATED APPLICATIONS

This application is based upon and claims the benefit of priority from the prior Japanese Patent Application No. 2001-252437, filed Aug. 23, 2001, the entire contents of which are incorporated herein by reference.

### BACKGROUND OF THE INVENTION

1. Field of the Invention

The present invention relates to a power transistor which has small power losses and operates at high speeds for use in power electronics circuits of switch-type power supply, inverter, synchronous rectifier, RF power supply, motor-drive power supply, etc., a semiconductor substrate for devices, and a method for manufacturing the semiconductor substrate for devices.

2. Description of the Related Art

To prevent the global warming, a reduction in electric power consumption in carbon dioxide terms is demanded on a global scale. For example, in switch-type power supplies of air conditioners and electric vehicles, importance is attached to raising the energy utilization efficiency by reducing power losses in order to achieve energy savings and effective utilization of the charge power of batteries. Suppressing power losses in motor-drive power circuits reduces the size of radiation fins for cooling and hence has the advantage that this leads to a miniaturization and lower cost of equipment.

In order to suppress power losses in power electronics circuits, research and development has so far been conducted on the introduction of an inverter method based on the use of electronic switches and the optimization of drive methods. However, these improvements of power electronics circuits especially in software have almost reached their limitations. Therefore, the conventional software-type improvements alone produce very little effect in a reduction of power consumption. Furthermore, in order to break through the present status, it is necessary to improve the performance of elements (power transistors) themselves, which are built in power electronics circuits.

Conventional power transistors are classified into a metal oxide semiconductor field effect transistor (hereinafter referred to as a MOSFET), an insulated gate bipolar transistor (hereinafter referred to as an IGBT) and a homojunction bipolar transistor (hereinafter referred to as an HMBT). These power transistors are selected and used as elements of circuit design according to their characteristics.

Incidentally, in order to reduce power consumption in circuits, increasing a switching speed of power transistor as circuit components and decreasing an on-state voltage drop of power transistor during ON-operation are the most effective means.

FIG. 5 is a map which shows the correlation between the on-state voltage drop (V) and switching time (μs) of various types of power transistors. At an assumed breakdown voltage of 280 V and an assumed current density of 100 A/cm², the performance of each transistor was evaluated and the tendency of the performance was schematically shown. In the figure, the symbol SiBT indicates a silicon/silicon homojunction bipolar transistor (an HMBT) and the symbol SiGeBT indicates a silicon germanium/silicon heterojunction bipolar transistor (hereinafter referred to as an HTBT).

Regardless of the type of components, there is a general tendency that switching time increases in proportion to the on-state voltage drop. The switching time of a MOSFET is shorter than that of an IGBT and a SiBT with the exception of a SiGeBT. Furthermore, the on-state voltage drop of a SiBT is lower than that of a MOSFET and an IGBT with the exception of a SiGeBT.

Incidentally, the present inventors proposed a SiGeBT in the specifications etc. of the U.S. patent Ser. Nos. 09/864,248, 10/103,743 and 10/012,399. A SiGeBT is excellent in energy-saving effect, heat liberation effect and miniaturization effect in comparison with the conventional MOSFET, IGBT and SiBT, and it is expected that a SiGeBT will be preferably used in power converters, such as a switch-type power supply, a motor-drive power supply, an inverter, a synchronous rectifier and an RF power supply.

In such a SiGeBT, the condition of a SiGe/Si heterojunction portion exerts a great influence on the properties of the transistor. That is, it is required that the “crystallizability” and “flatness” of a SiGe/Si heterojunction portion be sufficient. In order to ensure sufficient crystallizability and flatness of this portion, it is necessary to clean the surface of a Si substrate before the deposition of a SiGe film. By improving the crystallizability and flatness of this portion, it is possible to obtain the merits of high breakdown voltage properties and high yields in manufacturing. In order to obtain sufficient crystallizability and flatness of this portion, it is required that a film deposition apparatus be simple in construction and have a high yield.

### BRIEF SUMMARY OF THE INVENTION

An object of the present invention is to provide a power transistor which has small power losses and operates at high speeds and a method for manufacturing the power transistor.

Another object of the invention is to provide a semiconductor substrate which has sufficient crystallizability and flatness, ensures a high yield and can realize high breakdown voltage design of electronic devices and a method for manufacturing the semiconductor substrate.

As the present inventors described in the specifications of the U.S. patent Ser. No. 09/864,248 etc., the base layer of a SiGeBT can be designed as low-input impedance and a higher speed is ensured in comparison with a conventional SiBT (HMBT)

A SiGe film (base layer) is a film in which Si and Ge are in a state of mixed grains and the crystal structure of SiGe is similar to that of diamond. Usually, SiGe having a Ge concentration of not more than 50% is used. The SiGe film is deposited on a Si substrate as a film. Chemical vapor deposition such as the plasma CVD process is employed as a technique for forming a SiGe film.

A Si substrate is introduced into a vacuum vessel and placed on a substrate bed. The Si substrate is heated to a high temperature of not less than 60° C. while placed on the substrate bed. Silicon compound gases (SiH₄, Si₂H₆) and a germanium compound gas (GeH₄) are introduced into the vacuum vessel in such a heated condition. The silicon compound gases and the germanium compound gas react thermochemically in an atmosphere at an appropriate pressure and an appropriate temperature. As a result, Si atoms and Ge atoms precipitate on an exposed surface of the Si substrate and a SiGe film is laminated and deposited on the Si substrate as a film of SiGe mixed grains.

Such film deposition is carried out according to the following procedures. A Si substrate is transferred from a sample exchange chamber onto a substrate bed. The temperature of the Si substrate is set at 900 to 1000° C. The Si substrate heating time at such temperatures is tens of minutes maximum. The oxygen and carbon of the surface of the Si substrate are removed by this heating. In this removal, after the cleaning of the surface, a temperature for depositing a film on the Si substrate is set. An appropriate film deposition temperature is usually 600 to 800° C. The above gas mixture is introduced into the vacuum chamber the temperature of which is set at a film deposition temperature. The film deposition is finished with the stop of the introduction of the gas mixture or temperature lowering. The film thickness of the deposited SiGe film is adjusted by film deposition time and gas supply pressure. The Ge concentration of the SiGe film is adjusted by the mixture ratio of the gas mixture.

In order to improve transistor performance and increase a yield in manufacturing, it is required that a SiGe film deposited on a Si substrate be flat and free from defects. There are two causes of deterioration of the crystallizability and flatness of a SiGe film. One is a dislocation by strain relaxation that occurs in the SiGe film during deposition. The other is smudges (oxygen, carbon, fluorine or metal ions such as Na) existing on the surface in the initial deposition period after surface cleaning. Defects show uneven appearance with projections and depressions, for example, as shown in FIG. 3A. The projections and depressions of defects have, for example, a pyramidal shape. In this specification, such a defect is called a stacking fault. If a stacking fault exists, a leakage current becomes apt to occur between a base and a collector and this may deteriorate the breakdown voltage of a transistor. Furthermore, if the flatness of a substrate is bad, this may cause a deterioration in the working accuracy and yield in succeeding processes.

Film strains occur due to a slight difference in lattice constant between a SiGe film and a Si substrate which provides the base for the SiGe film. Because the lattice constant of a SiGe film increases with increasing Ge concentration, the expansion and contraction of lattices occurs near the contact interface of the contact structure of a SiGe film/Si substrate. Such expansion and contraction is the cause of the occurrence of strains. If strains occur, a crystal defect called a dislocation occurs in the SiGe film. Such a crystal defect induces a stacking defect, with the result that a SiGe film in which the stacking defect occurred becomes apt to produce many defects and, at the same time, flatness becomes lost. In order to suppress the inducement of such a stacking defect, it becomes necessary to limit the difference in the Ge concentration between the two layers of the contact structure and the film thickness of the layers.

Results of an investigation of the conditions of Ge concentration difference and film thickness conditions under which the occurrence of defects is prevented, are reported by Bean et al. on page 925, Volume 54, 1989, of Applied Physics Letters. Although irregularities of crystallizability and flatness based on the effect of smudges can be avoided under these conditions, the suppression of the occurrence of defects based on the effect of smudges is still difficult. Much time is required to keep the cleanness of a film deposition apparatus carried out to minimize smudges. As smudges on a film surface in the initial period of deposition, the adhering of impurities such as oxygen, carbon, fluorine and metal ions, to the surface is considered. Conventionally, a reduction of impurities is performed by chemically cleaning the substrate surface before film deposition and then performing high-temperature heat treatment of the interior of the vacuum vessel, which is called surface cleaning. As a representative example of chemical cleaning, the RCA process which is adopted in Si device production plants is generally known as a chemical cleaning technique (W. Kern and D. A. Puotinen RCA Rev. Vol. 31 (1970) 187.).

A typical RCA process is carried out by the following procedures 1) to 12):

1) Cleaning with ultra pure water for several minutes

2) Immersion in a mixed solution of NH₄OH, H₂O₂ and H₂O (ratio: 1:2:7) at 75° C. for more than several minutes

3) Cleaning with ultra pure water for several minutes

4) Immersion in 1% hydrofluoric acid at room temperature for several minutes

5) Cleaning with ultra pure water for several minutes

6) Immersion in a mixed solution of HCl, H₂O₂ and H₂O (ratio: 1:2:7) at room temperature for more than several minutes

7) Cleaning with ultra pure water for several minutes

8) Immersion in 1% hydrofluoric acid at room temperature for several minutes

9) Cleaning with ultra pure water for several minutes

10) Immersion in a mixed solution of H₂SO₄, H₂O₂ and H₂O (ratio: 1:2:7) at room temperature for more than several minutes

11) Cleaning with ultra pure water for several minutes

12) Spin rotation drying

By adopting this RCA process, impurities, in particular, carbon, metal ions and fine particles on the substrate surface before film deposition are removed. However, although carbon and oxygen are reduced by the RCA process to a certain degree, they are not thoroughly removed. After the chemical cleaning by the RCA process, the substrate is heated in a vacuum and adatoms are removed from the substrate surface, thereby cleaning the surface of the substrate. By this surface cleaning treatment, the oxygen atom density is usually reduced to a level of 10¹² atoms/cm². The carbon atom density is usually reduced to a level of 10¹³ atoms/cm².

Although the surface cleaning treatment can reduce the impurity atom density of oxygen etc. to a level of 10¹² atoms/cm², it is impossible to sufficiently suppress the carbon atom density. In a case where the film deposited on the Si substrate is a SiGe film, it is known from experience that a stacking fault occurs easily if atoms are present on the substrate surface at an atom density of 10¹³ atoms/cm² or so. Thus, in the case of the SiGe/Si heterojunction, it is difficult to suppress the occurrence of stacking faults by a combination of the chemical cleaning process (the RCA process) and a surface cleaning process (the heating process) alone.

Incidentally, in a case where a Si layer is deposited on the Si substrate, it is known that a stacking fault does not occur when carbon atoms remain at an atom density of 10¹³ atoms/cm² or so. In the case of the Si/Si homojunction, the defect density is controlled to not more than 1000 defects per cm² and this level is negligible.

Because of the above technical background, in order to reduce the carbon density within the film deposition apparatus, conventionally, the interior of the film deposition apparatus is repeatedly cleaned and close attention is paid to keeping the cleanness of the interior of the apparatus. Furthermore, in order to directly remove carbon, attempts have been made to remove carbon atoms by the halogen etching process by introducing halogen gases such as Cl₂ and F₂. However, much time is required to clean the interior of the film deposition apparatus. In addition, it becomes necessary to add new equipment for halogen gas etching, with the result that both equipment cost and maintenance cost become very large.

On the other hand, by accepting, as a precondition, the conception that stacking faults exist inevitably at the SiGe/Si heterojunction boundary, the SiGe film may sometimes be deposited with a thin film thickness in order to suppress the deterioration of surface flatness. When the SiGe film is deposited with a thin film thickness, it is necessary that the thickness of the SiGe film be controlled to not more than 0.1 μm. However, the use of such a thin SiGe film is limited to transistors for small signals and such a SiGe film cannot be used in power transistors.

Therefore, the present inventors have earnestly accumulated their experiences in research and completed the present invention, which will be described below.

The semiconductor substrate for devices of the present invention comprises an n⁺ conductive-type Si substrate 61, which has a surface intended for laminating, which is cleaned by wet type chemical cleaning treatment and further cleaned by heated cleaning treatment in a vacuum, an n⁻ conductive-type Si buffer layer 63, which is deposited on the above-described Si substrate as a lamination by a chemical vapor deposition process so as to completely cover impurities 62 remaining on the above-described surface intended for laminating, and a p conductive-type SiGe base layer 64, which is deposited as a lamination on the above-described Si buffer layer by a chemical vapor deposition process (refer to FIG. 2).

The Si substrate 61 comes into the air in the preparatory stage before film deposition and impurities in the air (mainly oxygen and carbon) adhere to the surface (the surface intended for laminating) of the Si substrate 61, the adhering including chemical adsorption. This oxygen, which forms a natural oxide film of SiO₂, can be completely removed by wet type chemical cleaning treatment and heated cleaning treatment in a vacuum. On the other hand, carbon cannot be completely removed by performing by wet type chemical cleaning treatment and heated cleaning treatment in a vacuum alone. If the SiGe layer is laminated on the Si substrate 61, the impurity layer 62 is formed and this impurity layer 62 generates defects at the heterojunction interface.

In the invention, therefore, the Si buffer layer 63 is formed on the Si substrate 61. This Si buffer layer 63 keeps the SiGe layer 64 away from the impurity layer 62 on the Si substrate 61 thereby to effectively prevent a lamination fault from occurring on the SiGe layer 64 and, at the same time, to effectively prevent a deterioration in flatness.

As the effect of the prevention of a deterioration in the flatness of this SiGe/Si boundary, breakdown voltage is improved and besides a yield is improved when this SiGe/Si boundary is used in electronic devices (for example, transistors and diodes). The Si substrate 61 is contaminated before introduction into a vacuum vessel, and the carbon of the surface portion 62, which is not removed and remains, is covered with the Si buffer layer 63 of lower impurity concentration and kept away from the SiGe layer 64.

It is necessary that the buffer layer 63 have a film thickness of not less than 5 nm. If the film thickness of the buffer layer 63 is less than 5 nm, the effect of covering the impurity layer 63 with the Si buffer layer 63 becomes insufficient. It is more preferred that the film thickness of the Si buffer layer 63 be larger than 10 nm. However, because increasing the film thickness of the Si buffer layer 63 without limitation increases the cost of manufacturing and is uneconomical, the maximum film thickness is 100 nm. This is because with a film thickness exceeding 100 nm, the effect of covering impurities with the Si buffer layer 63 reaches its maximum and does not increase any more.

It is preferred that the defect density of the SiGe layer 64 be not more than 5000 defects/cm². The film thickness of the Si buffer layer 63 and the defect density of the SiGe layer 64 are in a proportionally increasing relation. It is more preferred that the film thickness of the Si buffer layer 63 be larger than 10 nm and that, at the same time, the defect density of the SiGe layer 64 be not more than 1000 defects/cm².

The semiconductor substrate of the invention is preferably used, particularly, in a SiGe/Si heterojunction bipolar transistor. And such a power transistor is preferably used as a circuit element of various power converters, such as a switch-type power supply, a motor-drive power supply, an inverter, a synchronous rectifier and a RF power supply. Furthermore, such power converters are preferably used in motors comprising a rotor and a stator.

The power transistor of the invention comprises an n⁺ conductive-type Si substrate 61, which has a surface intended for depositing, which is cleaned by wet chemical cleaning and further cleaned by heated cleaning in a vacuum, an n⁻ conductive-type Si buffer layer 63, which is deposited on the above-described Si substrate as a deposition by a chemical vapor deposition process so as to cover impurities 62 remaining on the above-described surface intended for depositing, a p conductive-type SiGe base layer 64, which is deposited as a deposition on the above-described Si buffer layer by a chemical vapor deposition process, an n conductive-type Si emitter layer 74, which is provided on the above-described SiGe base layer, a base electrode 75, which is formed either by removing part of the above-described Si emitter layer or by reversing the conductive type of part of the above-described Si emitter layer, whereby a metal terminal is bonded to the portion remaining after removal or the reversed portion, an emitter electrode 76, which is formed by bonding a metal terminal to the above-described Si emitter layer, and a collector electrode 77, which is formed by bonding a metal terminal to the above-described Si substrate (refer to FIG. 7).

The method for manufacturing the power transistor of the invention comprises the steps of:

(a) preparing an n⁺ conductive-type Si substrate, cleaning a surface thereof intended for depositing by wet chemical cleaning and further cleaning the surface by heated cleaning in a vacuum;

(b) charging the Si substrate into a vacuum vessel and depositing an n⁻ conductive-type Si buffer layer as a deposition on the Si substrate by a chemical vapor deposition process so as to cover impurities remaining on the surface intended for depositing;

(c) subsequently depositing, in the vacuum vessel, a p conductive-type SiGe base layer as a deposition on the Si substrate by a chemical vapor deposition process;

(d) subsequently depositing, in the vacuum vessel, an n conductive-type Si emitter layer on the SiGe base layer by a chemical vapor deposition process;

(e) forming a base electrode either by removing part of the Si emitter layer or by reversing the conductive type of part of the Si emitter layer, whereby a metal terminal is bonded to the portion remaining after removal or the reversed portion;

(f) forming an emitter electrode by bonding a metal terminal to the Si emitter layer; and

(g) forming a collector electrode by bonding a metal terminal to a rear surface of the Si substrate.

The method for manufacturing the semiconductor substrate for devices of the invention comprises the steps of: (a) preparing an n⁺ conductive-type Si substrate, cleaning a surface thereof intended for depositing by wet chemical cleaning and further cleaning the surface by heated cleaning in a vacuum, (b) charging the above Si substrate into a vacuum vessel and depositing an n⁻ conductive-type Si buffer layer as a deposition on the above Si substrate by a chemical vapor deposition process so as to cover impurities remaining on the above surface intended for depositing, and (c) subsequently depositing, in the above vacuum vessel, a p conductive-type SiGe base layer as a deposition on the above Si substrate by a chemical vapor deposition process (refer to FIG. 1 and FIGS. 6A to 6D).

It is important to chemically clean the Si substrate 61 before introduction into a vacuum vessel 21. It is preferred that the step of taking the Si substrate 61 out of the vacuum vessel 21 after the deposition of the SiGe layer 64 and, after this takeout step, the step of cleaning the side exposed surface of a junction region between the Si substrate 61 and the SiGe layer 64 be further added. Leaks are suppressed by this side cleaning. In the step of cleaning the exposed side surface in the p-n junction region, it is possible to clean hydrocarbon and to remove germanium oxide. The step of cleaning hydrocarbon is carried our before step of removing germanium oxide, and it is effective that a cleaning liquid for cleaning hydrocarbon contains hydrofluoric acid and that a cleaning liquid for removing Ge oxide contains sulfuric acid.

Incidentally, in the surface cleaning of the n⁺ conductive-type Si substrate, the chemical cleaning process disclosed by the present inventors in the copending U.S. patent application Ser. No. 10/012,399 may be used in place of the above-described RCA process.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the embodiments given below, serve to explain the principles of the invention.

FIG. 1 is an internal sectional perspective view of an apparatus used in the manufacture of a semiconductor substrate of the invention.

FIG. 2 is a longitudinal sectional view of a semiconductor substrate related to en embodiment of the invention.

FIG. 3A is a photograph of the surface of a semiconductor substrate in a comparative example, which is taken by a scanning electron microscope (SEM).

FIG. 3B is a photograph of the surface of a semiconductor substrate related to an embodiment of the invention, which is taken by a scanning electron microscope (SEM).

FIG. 4 is a bar graph which shows a comparison of losses between a transistor of an embodiment and a transistor of a comparative example.

FIG. 5 is a schematic map of the performance of various types of transistors (switching time and on-state voltage drop).

FIGS. 6A to 6D are flow charts which shows a method for manufacturing a semiconductor substrate related to an embodiment of the invention.

FIG. 7 is a longitudinal sectional view of a transistor (SiGe/SiHTBT) related to an embodiment of the invention.

FIG. 8 is a longitudinal sectional view of a transistor (MOSFET) of a comparative example.

### DETAILED DESCRIPTION OF THE INVENTION

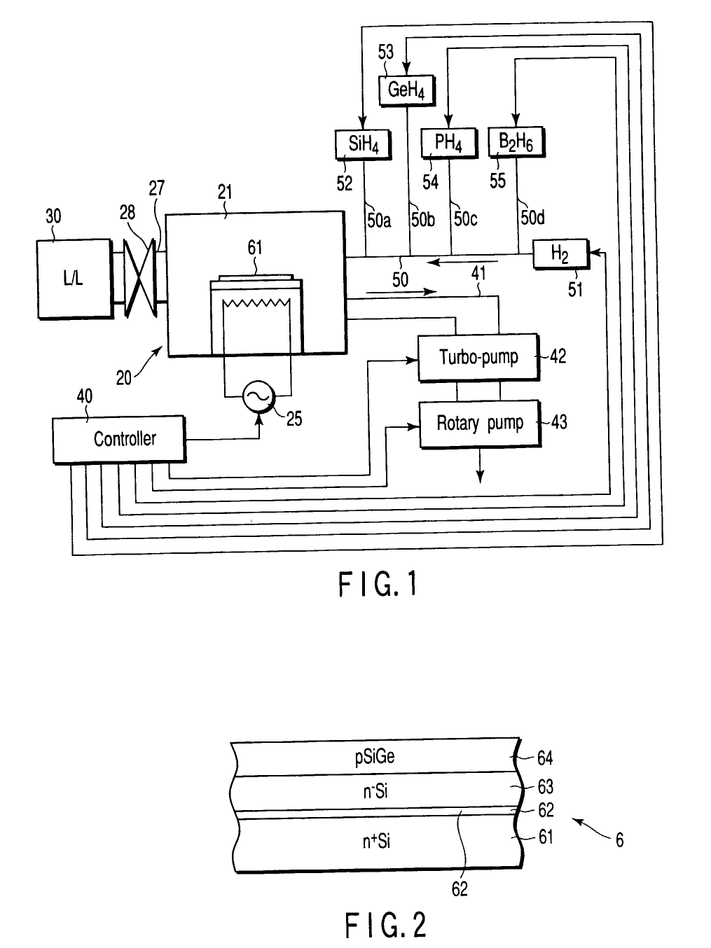

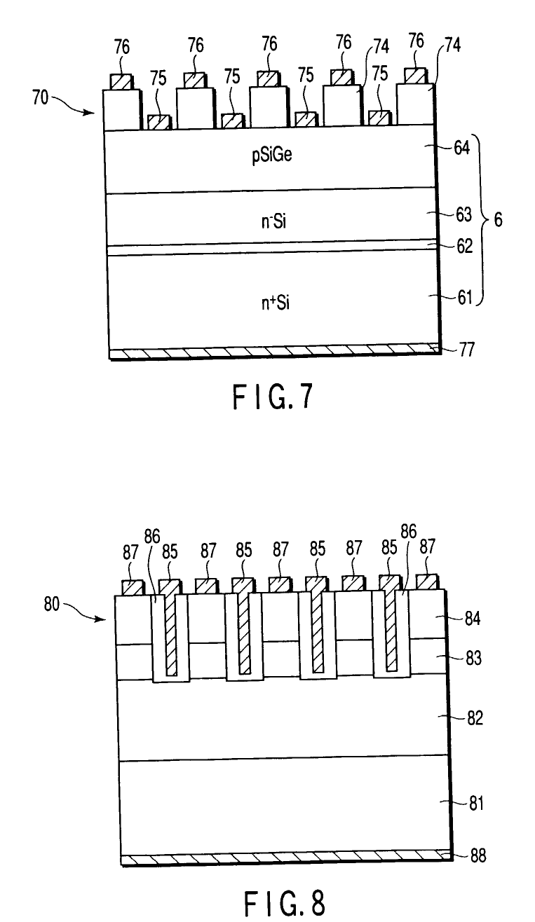

The semiconductor substrate for devices and power transistor of the invention are manufactured by use of reduced pressure CVD equipment shown in FIG. 1. The manufacturing process comprises a series of steps shown in FIGS. 6A to 6D and FIG. 7.

A chamber 20 and a load-lock chamber 30 of the reduced pressure CVD equipment are connected together by a substrate transfer passage 27 to as to permit communication. Both communicate with each other when a gate valve 28 is opened and both are cut off from each other when the gate valve 28 is closed. A semiconductor substrate 61, which is a raw material for transistors, is transferred from the outside by a transfer mechanism (not shown) into the chamber 21 of the CVD equipment via the load-lock chamber 30 and is then transferred from the chamber 21 via the load-lock chamber 30 to the outside. Incidentally, an opening 26 of the substrate transfer passage 27 is provided in the side surface of one side of the chamber 21.

An exhaust chamber 41 opens to the side surface of the other side of the chamber 21. In this exhaust chamber 41 are provided a turbo molecular pump 42 and a rotary pump 43 so that the interior of the chamber 21 is evacuated to produce a high vacuum. The turbo molecular pump 42 is disposed in the exhaust passage 41 on the upstream side in comparison with the rotary pump 43 (near the chamber 21) and used to perform precision exhausting after rough exhausting by use of the rotary pump 43.

In the chamber 21 is provided a stage 23, on which the substrate 61 is to be placed. In the stage 23 is built a heater 24, which heats the substrate 61. This stage 23 is provided with a cooling passage (not shown) and the stage 23 is forcedly cooled by causing a coolant to flow through this cooling passage from a coolant supply source (not shown).

A temperature sensor (not shown) is attached to the stage 23 so that the temperature of the substrate 61 or stage 23 can be detected. The temperature sensor is connected to the entry side of a controller 40. When a temperature detection signal is input, the controller 40 controls a heater power source 25 on the basis of the signal.

Five gas supply sources 51, 52, 53, 54, 55 communicate with the chamber 21 through pipes 50, 50a, 50b, 50c, 50d respectively. The first gas supply source 51 supplies hydrogen gas (H₂) into the chamber 21 through the main pipe 50. Hydrogen gas (H₂) is used to dilute film deposition gas and doping gas. The second gas supply source 52 supplies silane gas (SiH₄) or disilane gas (Si₂H₆) into the chamber 21 through the branch pipe 50a and main pipe 50. The third gas supply source 53 supplies germane gas (GeH₄) into the chamber 21 through the branch pipe 50b and main pipe 50. The fourth gas supply source 54 supplies phosphine gas (PH₃) into the chamber 21 through the branch pipe 50c and main pipe 50. The fifth gas supply source 55 supplies diborane gas (B₂H₆) into the chamber 21 through the branch pipe 50d and main pipe 50.

Each of the gas supply sources 51, 52, 53, 54 has a pressure control valve and a mass flow controller built therein (not shown). The controller 40 controls each of these pressure control valves and mass flow controllers, whereby the flow rates of the four kinds of gases are controlled with high accuracy and the gasses enter the main pipe 50, are mixed at a prescribed ratio and introduced into the chamber 21.

Incidentally, in addition to the heater source supply 25, the operation of each power supply of the turbo molecular pump 42 and rotary pump 43 is also controlled by the controller 40.

Embodiment 1

An n⁺ conductive-type epitaxial silicon wafer 61 was prepared as a starting material. The surface portion of the EPI Si wafer 61 is doped with at least one kind selected from phosphorus (P), arsenic (As) and antimony (Sb) is doped. When the dopant is a simple body of phosphorus (P), the doping concentration is 8×10¹⁹/cm³ or so. When the dopant is a simple body of arsenic (As), the doping concentration is 1×10¹⁹/cm³ or so. When the dopant is a simple body of antimony (Sb), the doping concentration is 1×10¹⁹/cm³ or so.

The EPI Si wafer 61 was chemically cleaned in accordance with the above RCA procedures 1) to 12) and foreign substances (mainly oxygen and carbon) were removed from the surface of the Si wafer 61 (step S1).

The Si wafer 61 after cleaning treatment was transferred into the chamber 21 of the CVD equipment and placed on the stage 23. The gate valve 28 was closed and the interior of the chamber 21 was vacuumed by use of pumps 42, 43 until the inner pressure reached 1×10⁻⁹ Torr. Subsequently, as shown in FIG. 6B, the Si wafer 61 was heated by the heater 24 to a temperature of 900±2° C. and held at this temperature for 5 minutes (step S2). In this step S2 of surface cleaning treatment, foreign substances (mainly oxygen and carbon) are further removed from the surface of the Si wafer 61. At this time, the removal of carbon is insufficient although the removal of oxygen is sufficient.

The power feed amount to the heater 24 was adjusted and, at the same time, a coolant was caused to flow through the cooling passage, and the temperature of the stage 23 was caused to drop during the temperature measurement by use of the temperature sensor. Eventually, the temperature of the Si wafer 61 was stabilized to 800±2° C.

After the stabilization of the temperature of the wafer 61 to 800±2° C., Si₂H₂ was introduced into the chamber 21 at a pressure of 2×10⁻⁴ Torr for about 1 minute. As shown in FIG. 6C, by this introduction of Si₂H₆, a Si buffer layer 63 with a film thickness of 30 nm was deposited on the Si wafer 61 (step S3). Incidentally, the impurity layer 62 was written in the figure for convenience. This impurity layer 62 was not deposited on purpose. Because a not negligible amount of carbon remains on the surface of the Si wafer 61 even after the step S2, the impurity layer 62 which contains this residual carbon was also shown.

After the evacuation of the interior of the chamber 21, a raw material gas for depositing the SiGe layer 64 was introduced into the chamber 21. Disilane gas (Si₂H₆), germane gas (GeH₄) and diborane (B₂H₆) were used as the raw material gas. A prescribed dilution rate was obtained by diluting this raw material gas at a prescribed flow rate of hydrogen gas. Furthermore, the temperature of the Si wafer 61 was adjusted to 700° C. The gas pressure of Si₂H₆ and GeH₄ was set at 2×10⁻⁴ Torr and 4×10⁻⁵ Torr, respectively. The B dope concentration of the p type SiGe film 64 is determined by the mixture ratio of diborane to disilane. In order to obtain a B dope concentration of 2×10¹⁷/cm³ or so, B₂H₆ partial pressure/Si₂H₆ partial pressure (or SiH₄ partial pressure) was set at 20 ppm or so.

Under these pressure and temperature conditions, Si₂H₆ and GeH₄ were caused to react according to the following reaction formulas. By this reaction, as shown in FIG. 6D, the p type SiGe film 64 was deposited on the n type Si buffer layer 63 (step S4). For the SiGe film 64, the boron (B) dope concentration was set at about 2×10¹⁷/cm³ and the film thickness was set at 200 nm.

Si₂H₆ Adsorption:

Si₂H₆ (gas)+2Si→2Si−(adsorbed)+6H (adsorbed)

GeH₄ Adsorption:

GeH₄ (gas)+4Si→2Ge (adsorbed)+4H (adsorbed)

H Desorption:

2H (adsorbed)→H₂ (gas)

When the introduction time of a mixed gas of Si₂H₆ and GeH₄ is 10 minutes, the film thickness of the SiGe film 64 is about 200 nm and the germanium concentration in the SiGe film is about 5 atom %. This film thickness and Ge concentration are not in the range of conditions under which dislocations and stacking faults by strains occur. The stacking fault density actually obtained is a level of hundreds per cm² and crystallizability which is sufficient for practical use is obtained. Thus, the occurrence of stacking faults due to carbon impurities is effectively avoided.

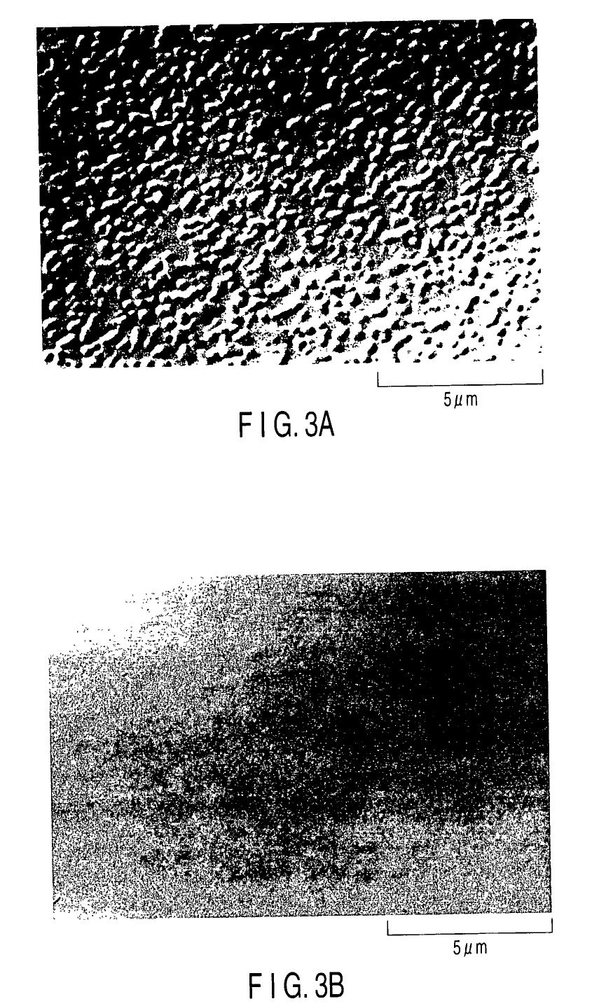

As shown in FIG. 6D, the impurity layer 62 containing carbon is completely covered with the Si buffer layer 63. Because in the semiconductor substrate 6 of the embodiment 1 carbon does not exist on the front surface side of the Si buffer layer 21, a stacking fault occurred neither in the Si buffer layer 21 or nor in the SiGe layer 64 as shown in FIG. 3A.

In contrast to this, in a comparative example in which the Si buffer layer 63 was not laminated and the SiGe layer is directly laminated on the Si wafer 61, a large number of stacking faults occurred as shown in FIG. 3A. The defect density observed was in the range of thousands to hundreds of thousands of defects per cm².

The heating by the heater was stopped and, at the same time, the interior of the chamber 21 was evacuated. The gate valve 28 was opened and the semiconductor substrate 6 was transferred from the chamber 21. The surface of this semiconductor substrate 6 was masked and the SiGe base layer 64 was pattern-etched by a wet type etching process or a dry type etching process, whereby a plurality of isolation trenches were formed (step S5). The trenches were formed at equal intervals and the base layer 64 is exposed at the bottom of each trench (groove).

As shown in FIG. 7, the base electrode 75 was formed by vapor-depositing aluminum on the exposed surface of the base layer 64 (step S6). Furthermore, the emitter electrode 76 was formed by vapor-depositing aluminum on the emitter layer 74 (step S7).

Moreover, the collector electrode 77 was formed by vapor-depositing aluminum on the rear surface of the Si substrate 61 (step S8). A laminate thus obtained was cut by a dicing machine at the trenches to form chips, and the surface of each of the chips was covered with a protective coating to obtain a bipolar transistor as the final product (step S9).

FIG. 7 shows a rough section of the transistor thus fabricated. The chip area of the bipolar transistor of the first embodiment was 0.16 mm². The emitter area was 0.1 cm² and the base area was 0.06 cm².

The density of impurities in the surface layer portion of the Si buffer layer 63 that covers the impurity portion 62 is lower than the impurity density of the Si substrate 61. The density of impurities is decreased by this Si buffer layer 63 and the flatness and crystallizability of the SiGe base layer 64 become excellent.

FIG. 3B is a micrograph which shows the mirror surface property of the surface of the SiGe base layer 64 of the invention. FIG. 3A is a micrograph which shows the non-mirror-surface property of the surface of a semiconductor substrate in a comparative example.

TABLE 1 shows the performance of the transistor of the embodiment and transistors of two comparative examples. The transistor of the embodiment was fabricated from the above semiconductor substrate. The transistors of the comparative examples were fabricated from the MOSFET and IGBT shown in FIG. 8.

The breakdown voltage of the transistor of the invention is 280 V and higher than that of the MOSFET of the comparative example, which is 75 V, and that of the IGBT of the comparative example, which is 250 V. The output current of the single transistor (SiGe/SiHTBT) of the invention is 20 A. It is possible to obtain 600 A by parallel connecting thirty transistors. The output current (600 A) exceeds the current output of the MOSFET of the comparative example, which is 82 A.

The current of the IGBT is 600 A, and in the transistor of the invention 600 A can be achieved by parallel connecting thirty transistors.

Incidentally, in the MOSFET, it is difficult to achieve high breakdown voltage while reducing losses.

Furthermore, in the IGBT, losses are large although it is easy to increase output.

In contrast to this, in the bipolar transistor of the invention, it is possible to obtain 600 A by a parallel connection, the on-state voltage drop is low, the switching speed is high, and losses are low.

TABLE 1

| | | Type | | | | | |
|---|---|---|---|---|---|---|---|
| Characteristic | | SiGe/SiHTBT | | MOSFET | | IGBT | |
| Output | Breakdown | 280 | V | 75 | V | 250 | V |
| | voltage | | | | | | |
| | Current | 600 | A | 82 | A | 600 | A |

(20 A × 30)

| | | | | | | |
|---|---|---|---|---|---|---|
| On-state voltage | 0.18 | V | 0.7 | V | 1.2 | V |
| drop | | | | | | |
| Switching time | 20 | ns | 62 | ns | 670 | ns |
| Loss | 2.7 | W | 11.2 | W | 14.6 | W |

The on-state voltage drop of the SiGe/SiHTBT produced from the semiconductor substrate 6 of the first embodiment was 0.18 V. This value is lower than the on-state voltage drop of the MOSFET of the comparative example, which is 0.7 V, and that of the IGBET of the comparative example, which is 1.2 V. The switching time of the SiGe/SiHTBT of the invention is 20 ns. This value is lower than the switching time of the MOSFET of the comparative example, which is 62 ns, and that of the IGBET of the comparative example, which is 670 ns.

The power loss of the SiGe/SiHTBT of the invention is 2.7 W (conditions of comparison: 20 A−6 kHz, 50% duty). This value is lower than the power loss of the MOSFET of the comparative example, which is 11.2 W, and that of the IGBT of the comparative example, which is 14.6. Also, owing to its low on-state voltage drop and high switching speed, the transistor of the invention is superior to the transistors of the comparative examples in power loss.

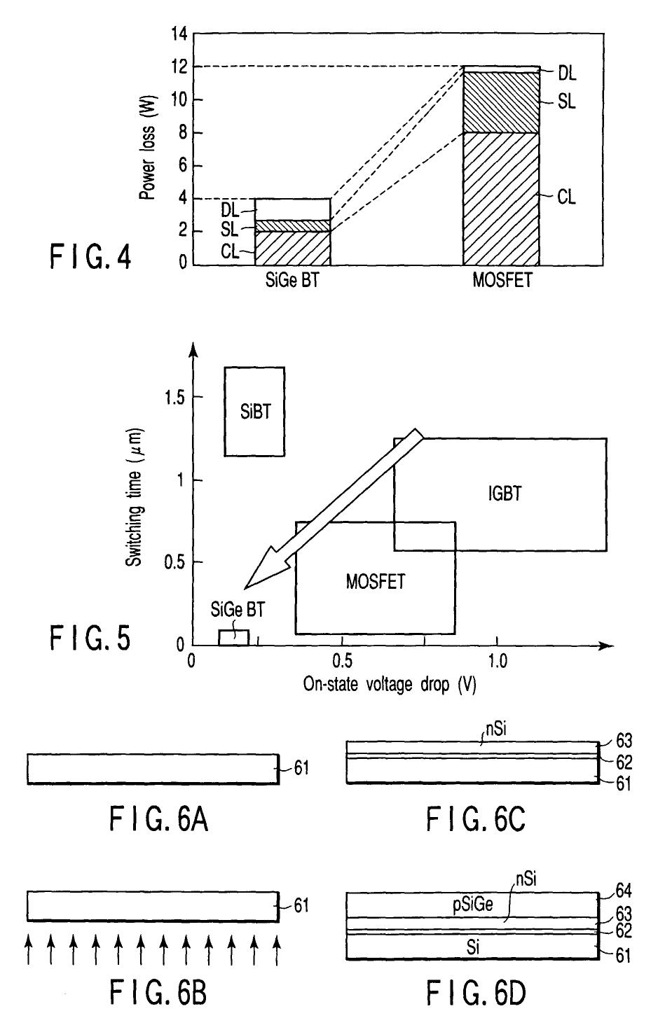

FIG. 4 shows a quantitative comparison of drive circuit loss DL, switching loss SL and ON operation loss CL. The transistor of the invention is by far superior to the MOSFET of the comparative example in the small switching loss SL and ON operation loss CL, which account for the greater part of the total loss.

FIG. 5 shows the interrelation between on-state voltage drop and switching time. Switching time increases in proportion to on-state voltage drop. In terms of power loss, which is in proportion to the product of on-state voltage drop and switching time, the transistor of the invention is superior to the IGBT and MOSFET of the comparative examples. As described above, the transistor of the invention is excellent in energy-saving effect, heat liberation effect and miniaturization effect because of low energy loss and is preferably used in power converters, such as a switch-type power supply, a motor-drive power supply, an inverter, a synchronous rectifier and an RF power supply.

Embodiment 2

Chemical treatment of the above-described RCA procedures 1) to 12) was carried out. The surface cleaning treatment is the same as that of the first embodiment. The setting of the temperature of the Si substrate 61 after that is the same as in the first embodiment. Although the introduction of Si₂H₆ at a pressure of 2×10 Torr⁻⁴ is the same as in the first embodiment, the time of introduction of Si₂H₆ in this second example is changed in the range of 10 seconds to 3 minutes (180 seconds). The film thickness of the laminated Si film 11 for a time in this range changes between 5 nm and 90 nm.

The introduction conditions and introduction time of the mixed gas and the heating conditions of the Si substrate 6 in the second embodiment are the same as in the first example. In the second embodiment, the film thickness of the SiGe film 12 is 200 nm and the Ge concentration thereof is 5 atom % and they are the same as in the first embodiment. This film thickness and Ge concentration are not in the range of conditions under which dislocations and stacking faults due to strains occur. When the thickness of the laminated Si film 11 was less than 5 nm, a large number of stacking faults considered to be due to the effect of carbon impurities occurred. That is, stacking faults occurred at high densities in the range of thousands to hundreds of thousands of defects per cm². When the thickness of the laminated Si film 11 was not less than 10 nm, defects could be suppressed to a stacking fault density of not more than 1000 defects/cm² with good reproducibility.

It is especially preferred that the exposed side surface of the junction region between the Si layer (including the Si buffer layer 63) and the SiGe layer be etched, next cleaned with a cleaning liquid containing hydrofluoric acid, further cleaned with a cleaning liquid containing sulfuric acid, and then coated with an insulator layer after the cleaning. The exposed side surface of the SiGe/Si junction region comes into contact with the air and is naturally oxidized. Due to this natural oxidation, on the exposed side surface mix in impurities (for example, hydrocarbon) and metal ions from the worker (for example, Na⁺ and K⁺) and besides oxidation occurs to form Ge₂ as impurities. Such impurities induce the occurrence of a leakage current and reduce the breakdown voltage of the semiconductor substrate.

Hydrofluoric acid removes such oxides. The junction region of the exposed side surface is terminated with hydrogen by this cleaning treatment. It is difficult to remove hydrocarbon by the cleaning with hydrofluoric acid. The sulfuric acid solution used in the next cleaning step dissolves metal impurities and hydrocarbon and removes them from the surface. In this step, the oxide film formed with a thickness of 1 nm or so is SiO₂ and the oxide of Ge, i.e., GeO₂ is not formed. GeO₂, which is formed by the oxidation of Ge atoms present on the surface layer due to the effect of sulfuric acid, dissolves in the sulfuric acid solution and will not remain in the surface layer. The Si oxide formed on the surface is inactive and can effectively suppress the adsorption of impurities after that.

FIG. 8 is a schematic sectional view of the MOSFET of the comparative example. The MOSFET 80 comprises an n⁺ type Si substrate 81, an n⁻ type Si layer 82, a p⁻ type Si layer 83, an n⁺ type Si well layer 84, a gate electrode 85, an insulating layer 86, a drain electrode 87, and a source electrode 88. The source electrode 88 is provided on the rear surface of the substrate 81. The drain electrode 87 is provided on the n⁺ type Si well layer 84. The p⁻ type Si layer 83 is interposed between the p type Si layer 82 and the n⁺ type Si well layer 84.

The gate electrode 85 is insulated by the insulating layer 86 extending along a contact hole from the three layers of n⁻ type Si layer 82, n⁻ type Si well layer 83 and n⁺ type Si well layer 84. Because the bottom end of the gate electrode 85 reaches the vicinity of the p type Si layer 82, the gate electrode 85 faces the n⁻ type Si layer 82 through the thin insulating layer 86.

When a bias voltage is applied to the gate electrode 85, electrons migrate from the n⁺ type Si well layer 84 to the n⁺ type Si substrate 81. That is, a current flows from the source electrode 88 to the drain electrode 87.

The lamination structure of the transistor having the SiGe layer according to the invention is simple in comparison with the MOSFET and excellent in productivity at low cost. A Si buffer layer 63 is formed on the SiGe layer 64 according to the invention. When flatness is required of the front surface side of the p-SiGe layer 64, the Si buffer layer 63 is formed between the substrate 61 (including layer 62) and the p-SiGe layer 64. The electrode forming method is not restricted by types such as the grate type, comb-shaped type and vortex type.

The power transistor of the invention is preferably used as a power converter in the motor drive circuit of a battery forklift and the inverter circuit of a wind power generator.

The semiconductor substrate and the method for manufacturing the semiconductor substrate according to the invention can realize high breakdown voltage in electronic devices (for example, transistors and diodes) in which the semiconductor substrate and the method for manufacturing the semiconductor substrate are used, reduce the cost of manufacturing by improving yields and realize a low-output-loss power converter.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A power transistor, comprising:
an n⁺ conductive-type Si substrate having a surface intended for depositing, which is cleaned by wet chemical cleaning and further cleaned by heated cleaning in a vacuum;
an n⁻ conductive-type Si buffer layer being deposited on the Si substrate as a deposition by a chemical vapor deposition process so as to cover impurities remaining on said surface intended for depositing;
a p conductive-type SiGe base layer being deposited as a deposition on the Si buffer layer by a chemical vapor deposition process;
an n conductive-type Si emitter layer being provided on the SiGe base layer;
a base electrode being formed either by removing part of the Si emitter layer or by reversing the conductive type of part of the Si emitter layer, whereby a metal terminal is bonded to the portion remaining after removal or the reversed portion;
an emitter electrode being formed by bonding a metal terminal to the Si emitter layer; and
a collector electrode being formed by bonding a metal terminal to the Si substrate.

2. The transistor according to claim 1, wherein density of the impurities in the Si buffer layer is lower on the side of the SiGe base layer than on the side of the Si substrate.

3. The transistor according to claim 1, wherein said impurities in the Si buffer layer are carbon.

4. The transistor according to claim 1, wherein said Si buffer layer has a thickness of not less than 5 nm.

5. The transistor according to claim 1, wherein the defect density of said SiGe base layer is not more than 5000 defects/cm².

6. The transistor according to claim 1, wherein said Si buffer layer has a thickness of not less than 10 nm.

7. The transistor according to claim 6, wherein the defect density of said SiGe base layer is not more than 1000 defects/cm².

8. The power transistor according to claim 1, wherein the breakdown voltage between said SiGe base layer and said Si substrate is 280 V.

9. A method for manufacturing a power transistor, comprising the steps of:
(a) preparing an n⁺ conductive-type Si substrate, cleaning a surface thereof intended for depositing by wet chemical cleaning and further cleaning the surface by heated cleaning in a vacuum;
(b) charging said Si substrate into a vacuum vessel and depositing an n⁻ conductive-type Si buffer layer as a deposition on the Si substrate by a chemical vapor deposition process so as to cover impurities remaining on the surface intended for depositing;
(c) subsequently depositing, in the vacuum vessel, a p conductive-type SiGe base layer as a deposition on the Si substrate by a chemical vapor deposition process;
(d) subsequently depositing, in the vacuum vessel, an n conductive-type Si emitter layer on the SiGe base layer by a chemical vapor deposition process;
(e) forming a base electrode either by removing part of the Si emitter layer or by reversing the conductive type of part of the Si emitter layer, whereby a metal terminal is bonded to the portion remaining after removal or the reversed portion;
(f) forming an emitter electrode by bonding a metal terminal to the Si emitter layer; and
(g) forming a collector electrode by bonding a metal terminal to a rear surface of the Si substrate.

10. The method according to claim 9, wherein the heating temperature is 900±2° C. in the heated cleaning in a vacuum.

11. A semiconductor substrate for devices, comprising:
an n⁺ conductive-type Si substrate having a surface intended for depositing, which is cleaned by wet chemical cleaning and further cleaned by heated cleaning;
a Si buffer layer being deposited on the Si substrate as a lamination by a chemical vapor deposition process so as to cover impurities remaining on the surface intended for depositing; and
a SiGe base layer being deposited as a deposition on the Si buffer layer by a chemical vapor deposition process.

12. The substrate according to claim 11, wherein density of the impurities in the Si buffer layer is lower on the side of the SiGe base layer than on the side of the Si substrate.

13. The substrate according to claim 11, wherein said impurities in the Si buffer layer are carbon.

14. The substrate according to claim 11, wherein said Si buffer layer has a thickness of not less than 5 nm.

15. The transistor according to claim 11, wherein defect density of the SiGe base layer is not more than 5000 defects/cm².

16. The transistor according to claim 11, wherein said Si buffer layer has a thickness of not less than 10 nm.

17. The transistor according to claim 16, wherein defect density of the SiGe base layer is not more than 1000 defects/cm².

18. A method for manufacturing a semiconductor substrate for devices, comprising the steps of:
(a) preparing an n⁺ conductive-type Si substrate, cleaning a surface thereof intended for depositing by wet chemical cleaning and further cleaning the surface by heated cleaning in a vacuum;
(b) charging said Si substrate into a vacuum vessel and depositing an n⁻ conductive-type Si buffer layer as a deposition on said Si substrate by a chemical vapor deposition process so as to cover impurities remaining on said surface intended for depositing; and
(c) subsequently depositing, in the vacuum vessel, a p conductive-type SiGe base layer as a deposition on the Si substrate by a chemical vapor deposition process.

19. The process according to claim 18, wherein the heating temperature is 900±2° C. in said heated cleaning in a vacuum.

20. The process according to claim 18, wherein after said step (c), the exposed side surface of a junction region between the Si substrate and the SiGe base layer is cleaned.

21. The process according to claim 20, wherein hydrocarbon is removed by wet chemical cleaning from the exposed side surface of said junction region and germanium oxide is removed by wet chemical cleaning from the exposed side surface of said junction region.
